(19) United States
(12) Patent Application Publication
(10) Pub. No.: US 2012/0027925 A1
(43) Pub. Date: Feb. 2, 2012

(54) METHOD AND DEVICE FOR PRODUCING SERIALLY CONNECTED SOLAR CELLS

(76) Inventor: Rainer MERZ, Tamm (DE)

(21) Appl. No.: 12/847,361

(22) Filed: Jul. 30, 2010

(51) Int. Cl. B05D 5/12; C23C 16/00

(52) U.S. Cl. 427/75; 118/721

(57) ABSTRACT

The invention discloses a method and an apparatus for production of series-connected thin-film solar cells on rigid substrates. A semi-finished product having a rigid mount substrate is arranged on a receptacle, and is introduced into a deposition chamber having a deposition device. Furthermore, a masking device having at least one masking means, which is in the form of a strand and is prestressed in the longitudinal direction, is applied to a surface of the semi-finished product facing the deposition device, wherein the masking means which is in the form of a strand preferably has a plurality of filaments which rest on one another. In order to structure a material layer to be deposited, the surface of the semi-finished product is partially shadowed by means of the masking device with respect to the deposition device.

The invention relates to a method for production of series-connected thin-film solar cells, which method has the steps of arrangement of a semi-finished product having a rigid mount substrate on a receptacle, introduction of the semi-finished product into a deposition chamber having a deposition device, and deposition of a material layer onto the semi-finished product.

Solar cells based on thin-film technology are distinguished in particular by the use of little material to produce the active layers and by a high potentially achievable efficiency. In order to reduce resistive losses and to produce a high output voltage, the active layers of the solar cells are normally structured on the substrate and are connected in series with one another.

Rigid materials can be used as a substrate for producing solar cells based on thin-film technology since this allows the very thin layers to be arranged on a firm base, thus making it possible to increase the mechanical robustness and to simplify handling during manufacture.

One method for producing a circuit of thin-film solar cells with glass substrates is known from WO 2007/044555 A2. In this case, active and conductive layers are deposited onto a substrate in a first process step, wherein individual layers, or all the layers, are then separated by a laser or mechanical scoring in order to apply an additional conductive layer, by a printing process or by electroplating, in order to deliberately connect specific active layers.

In an alternative method, the deposition process is in each case followed by a cutting process. In this case, the layer most recently deposited in each case, possibly together with further layers, is separated in order to make it possible to deliberately introduce conductive or active material into the separation area with the subsequent layer. Once the uppermost conductive layer, the front contact, has been applied, this layer, possibly together with further layers, is then cut open in order to prevent a short circuit of the front contacts of adjacent solar cells.

In principle, this makes it possible to manufacture solar cells using thin-film technology on glass substrates. However, it has been found that methods such as these are particularly complex and are therefore highly costly, since the respectively applied layers must be partially removed again in an additional process, for connection purposes. Separate, expensive laser cutting installations or mechanical scoring installations are required for this purpose. Furthermore, the glass substrate must, according to the method, be transferred in each case between a deposition process and a cutting process, since the deposition process is carried out in a vacuum chamber, and the cutting process is carried out in separate apparatuses. The transfer is particularly complex since it is necessary in each case to pass through a vacuum lock and, furthermore, the substrate temperature must be matched to the respective process temperatures used during deposition in a vacuum and during the cutting process.

Furthermore, passing the substrate repeatedly into and out of the vacuum lock can increase the risk of contamination both of the substrate and of the deposition device and of the cutting apparatus. This can lead to poorer process quality and to waste production.

WO 2007/085343 A1 discloses a method for production of series-connected solar cells having flexible substrates, in which the substrate is applied to a curved contact surface in a deposition device, and is shadowed with respect to the deposition device by means of at least one stressed wire which is placed on the substrate. The material layer to be applied is therefore structured during the deposition process itself. The stressed wire can advantageously be prestressed with respect to the flexible substrate such that this results in a sufficiently broad contact surface, in whose area no material can be deposited, by the deformation of the substrate, instead of simple line contact.

Furthermore, both the flexible substrate and the wire of the deposition device can be fed continuously or quasi-continuously, in order to allow continuous production of a structured material layer on the flexible mount substrate, in a continuous process.

However, it has been found that such solar cells with flexible substrates can be produced on an industrial scale only at high cost. In addition, solar cells such as these have only limited mechanical natural robustness and, for some applications, must therefore be provided with separate mount and protective layers.

The method is also not particularly suitable for production of thin-film solar cells with rigid substrates, since, because of the lack of capability for curvature and the lack of elasticity on the substrate surface, the wire cannot adequately shadow the rigid substrate, with respect to the deposition device, which can result in faults, in particular short circuits, in the structure of the material layer to be deposited.

In contrast, the production of solar cells on glass substrates is widespread, and has been proven on a large technological scale. However, it is complex and expensive to connect such solar cells in series.

Against this background, the invention is based on the object of specifying an improved method for production of thin-film solar cells with rigid substrates, which is as suitable as possible for advantageous, automated manufacture. A further aim is to specify an apparatus which is suitable for carrying out this method.

According to the invention, this object is achieved by a method for production of series-connected thin-film solar cells having the following steps:
arrangement of a semi-finished product having a rigid mount substrate on a receptacle;
introduction of the semi-finished product into a deposition chamber having a deposition device;
application of a masking device having at least one masking means, which is in the form of a strand and is prestressed in the longitudinal direction, to a surface of the semi-finished product facing the deposition device;
partial shadowing of the surface of the semi-finished product by means of the masking device from the deposition device in order to structure a material layer to be deposited;
deposition of the material layer onto the semi-finished product; and
release of the masking device from the surface of the semi-finished product.

In this way, the object of the invention is achieved completely.

Specifically, according to the invention, the masking device with the masking means in the form of a strand results in particularly good and reliable shadowing of the semi-finished product with the rigid mount substrate with respect to the deposition device. In this case, the masking means in the form of a strand must have a minimum thickness of 20 micrometres. In addition, adequate elasticity must be provided in order to create a flat contact (instead of a linear contact) between the rigid mount substrate and the masking means in the form of a strand. Otherwise, it is no longer possible to ensure adequate shadowing, thus resulting in a risk of short circuits.

According to the invention, the material layer to be deposited can be structured during the deposition process itself. This avoids the need for separate cutting processes for structuring a material layer, even in the case of thin-film solar cells with rigid substrates. Advantageous manufacture, which can be automated, can be achieved by the capability to use installations which have been proven on a large technological scale, for production of solar cells on glass substrates.

The masking means in the form of a strand ensures a high level of process reliability since reliable shadowing is ensured even when the substrate is only slightly curved, thus resulting in clean, uncoated separating surfaces, preventing short circuits, during the coating process.

For the purposes of this application, a “rigid mount substrate” means a mount substrate which, in contrast to a flexible mount substrate, can be bent only to a limited extent, that is to say allowing maximum bending with a bending radius of >100 cm. By way of example, this could be a plate composed of a glass, a glass ceramic material or a wafer. In the narrower sense, this means a mount substrate which allows maximum bending with a bending radius of >20 cm. Greater bending than this leads to destruction or damage, for example to continuous deformation, of the substrate. It has been found that glass plates tend to fracture with a smaller bending radius, and mount substrates in the form of rigid plastic panels or metal plates are damaged, for example by fracturing or being permanently deformed.

As already mentioned, the rigid mount substrate may be a substrate which consists of a glass material, a glass ceramic material, a wafer, a plastic or a metal.

This makes it possible to use a wide range of glass materials, glass ceramic materials or else wafers in order to form the rigid mount substrate. It is preferably possible to use materials which are particularly suitable for electronic applications, such as borosilicate glass with a proportion of barium oxide and aluminium oxide. Suitable glass materials and glass ceramic materials form a highly effective diffusion barrier, which means that there is no need for additional measures for this purpose. In addition, wafers can be used as mount substrates.

Furthermore, in principle, plastic panels and metal plates are also suitable as mount substrates.

In one preferred development, the masking means which is in the form of a strand has a plurality of filaments which rest on one another. For the purposes of this application, a “filament” means any type of elongated element. This may therefore be a metal wire, a plastic thread, for example consisting of polyamide, or a high-strength material such as aramid. It is also possible to use other inorganic materials which can conceivably be drawn out to form threads or fibres, such as C, BN, SiC etc. In any case, a cohesive, tension-resistant filament must be created, which has a thickness of at least 20 μm. In addition, particularly when using only a single filament, this must be deformable when placed on the rigid mount substrate to such an extent as to create an area contact, not only a linear contact, between the rigid substrate and the masking means in the form of a strand. Otherwise, adequate shadowing is not ensured, thus creating a risk of short circuits.

When a plurality of filaments resting on one another are used, this itself results in intermediate spaces which are screened from the outside and therefore ensure good screening from the plasma.

In one advantageous development of the invention, the semi-finished product has convex curvature with respect to the deposition device.

This makes it possible to ensure that a force component is created in the direction of the surface of the semi-finished product when the masking means is applied, which is prestressed in the longitudinal direction. This makes it possible to prestress the masking means particularly effectively with respect to the semi-finished product, thus resulting in even better shadowing of the surface of the semi-finished product with respect to the deposition device.

In this context, it should be noted that the bending stresses in the semi-finished product with the rigid mount substrate can remain considerably below the critical strength levels. Taking account of the high stiffness of the rigid mount substrate, little curvature can in consequence be achieved, although this can contribute considerably to further improving the process reliability.

In one preferred development of the invention, the at least one masking means carries out a relative movement in the longitudinal direction of the masking means with respect to the semi-finished product during the deposition of the material layer.

This measure allows particularly effective shadowing of the semi-finished product with respect to the deposition device to be achieved, and the process-dependent deposition of the material layer to be deposited on the masking means can be considerably reduced. This allows the process quality to be further improved and the effort for cleaning the masking device with the masking means can be reduced.

For the purposes of this application, the relative movement between the semi-finished product and the masking means in the longitudinal direction of the masking means can take place both by movement of the semi-finished product with respect to the stationary masking means or by movement of the masking means with respect to the stationary semi-finished product, as well as by simultaneous movement of the semi-finished product and of the masking means. In this case, the movements may be in the opposite sense, or else in the same sense, with different absolute velocities.

According to a further refinement of the invention, the at least one masking means is moved in and out continuously or quasi-continuously in the longitudinal direction.

This allows the method to be automated particularly well, since the masking means can be fed in and out for example using a revolving process or a roll-to-roll process.

In one preferred development of the invention, the at least one masking means is guided by at least one guide roller or is aligned by at least one centring means.

This allows the masking means to be fed in particularly accurately and deliberately, allowing shadowing losses to be minimized, and thus making it possible to improve even further the process accuracy and quality. The process of the filaments of the masking means resting on one another can likewise be assisted by suitable guidance and alignment of the masking means by guide rollers and/or centring means, in order to further improve the effectiveness of the shadowing.

According to a further refinement of the invention, the at least one masking means is loaded by a hold-down device transversely with respect to its longitudinal direction, essentially at right angles to the surface of the semi-finished product.

This measure also makes it possible to produce a force component at right angles to the surface of the semi-finished product, assisting the process of the masking means resting firmly on the surface of the semi-finished product, and therefore making it possible to further improve the shadowing of the surface of the semi-finished product with respect to the deposition device.

In an alternative refinement of the invention, the hold-down device has the at least one guide roller or the at least one centring means.

This allows various functions, such as holding down, alignment and guidance, to be combined, thus making it possible to considerably simplify the manufacturing process.

In one advantageous development of the invention, the at least one masking means is prestressed in the longitudinal direction by a stressing means, in particular a spring.

This allows the prestress to be applied particularly easily, for example by the stressing means acting directly on the masking means with its filaments, or by the stressing means interacting with the guide roller or the hold-down device, in order to indirectly introduce a prestress into the masking means.

According to a further refinement of the invention, a plurality of material layers are deposited onto the semi-finished product using a plurality of deposition chambers.

This makes it possible to use deposition chambers which are matched to the deposition process of the respective layer to be deposited, thus making it possible to reduce the cleaning or rinsing effort, resulting in improved manufacturing productivity. In particular, it is possible to use highly automated cluster or linear arrangements with a plurality of specialized deposition chambers for manufacture.

In one expedient development of the invention, the at least one masking means is offset transversely with respect to its longitudinal direction on the surface of the semi-finished product between the deposition of the material layers, in order to allow contact or separation of specific material layers.

This allows series-connected thin-film solar cells to be manufactured particularly effectively since each material layer can now be structured separately, and the previous separating structure for deposition of a new material layer can be released. This allows material to be deposited to adhere to the old separating structure, thus making it possible to make contact with different material layers particularly effectively and easily.

In one advantageous development of the invention, the deposition of the material layers and the offsetting of the at least one masking means are carried out in a process gas atmosphere or in a vacuum.

There is therefore no need to remove the semi-finished product and the masking device from the process gas atmosphere or the vacuum in order to offset the masking means. This makes it possible to reduce the manufacturing time, and production can be automated even better. Furthermore, lock processes for matching the semi-finished product or the masking device to the process conditions can be avoided, contamination is reduced, and fewer process residues can escape into the environment. In addition, the substrate remains at the same temperature, which is advantageous for component quality.

According to a further refinement of the invention, the offsetting of the at least one masking means is carried out in a separate offset chamber.

This makes it possible to use a specialized offset chamber in order to improve the manufacturing productivity even further. Furthermore, this improves the series-production compatibility of the method, since known deposition chambers can now be used, without any special fittings for offsetting the masking means.

In one expedient development of the invention, a transfer takes place between the deposition and the offsetting, during which the semi-finished product is still subject to the process gas atmosphere or the vacuum.

This measure allows the manufacturing steps to be carried out even for series-production-compatible specialization with a plurality of deposition chambers, an offset chamber and a transfer between the deposition and the offsetting, while still in the process gas atmosphere or in the vacuum.

According to a further refinement of the invention, dirt or residues of the deposited material layers are removed from the masking device by cleaning processes, in particular etching processes.

This allows the cleaning of the masking device to be integrated in the manufacturing process, and, in particular, established technologies and existing cleaning facilities for the individual chambers can be used for this purpose.

The object of the invention is also achieved by an apparatus for production of series-connected thin-film solar cells having at least one deposition chamber having a deposition device, having a receptacle for holding a semi-finished product with a rigid mount substrate, in particular a mount substrate consisting of a glass material, and having a masking device which can be fitted to the semi-finished product, wherein the masking device has at least one masking means which is in the form of a strand, can be prestressed in the longitudinal direction and can be aligned with respect to the semi-finished product for partial deposition of the semi-finished product with respect to the deposition device.

According to one development of the apparatus according to the invention, the masking means which is in the form of a strand has a plurality of filaments which rest on one another.

This improves the shadowing even further.

According to a further embodiment of the apparatus according to the invention, the receptacle for holding the semi-finished product has convex curvature with respect to the deposition device.

In one expedient development of the apparatus according to the invention, this apparatus has a plurality of masking means at a distance from one another.

In one advantageous development of the apparatus according to the invention, this apparatus has a plurality of deposition chambers for deposition of the material layers, an offset chamber with an offset device with offset means for offsetting the at least one masking means transversely with respect to its longitudinal direction relative to the surface of the semi-finished product, and a handling chamber with a handling device for feeding the semi-finished product into the chambers.

According to a further refinement of the apparatus according to the invention, a vacuum can be applied or a process gas can be supplied to the chambers.

An apparatus such as this allows the method according to the invention to be carried out in such a way as to allow thin-film solar cells to be produced on rigid substrates in an improved advantageous manner, which can be automated.

It is self-evident that the features of the invention mentioned above and those which are still to be explained in the following text can be used not only in the respectively stated combination but also in other combinations or on their own, without departing from the scope of the present invention.

Further features and advantages of the invention will become evident from the following description of preferred exemplary embodiments, and with reference to the drawings, in which:

FIG. 1 shows a sequence of layer structures of a semi-finished product during the production of solar cells using the method according to the invention;

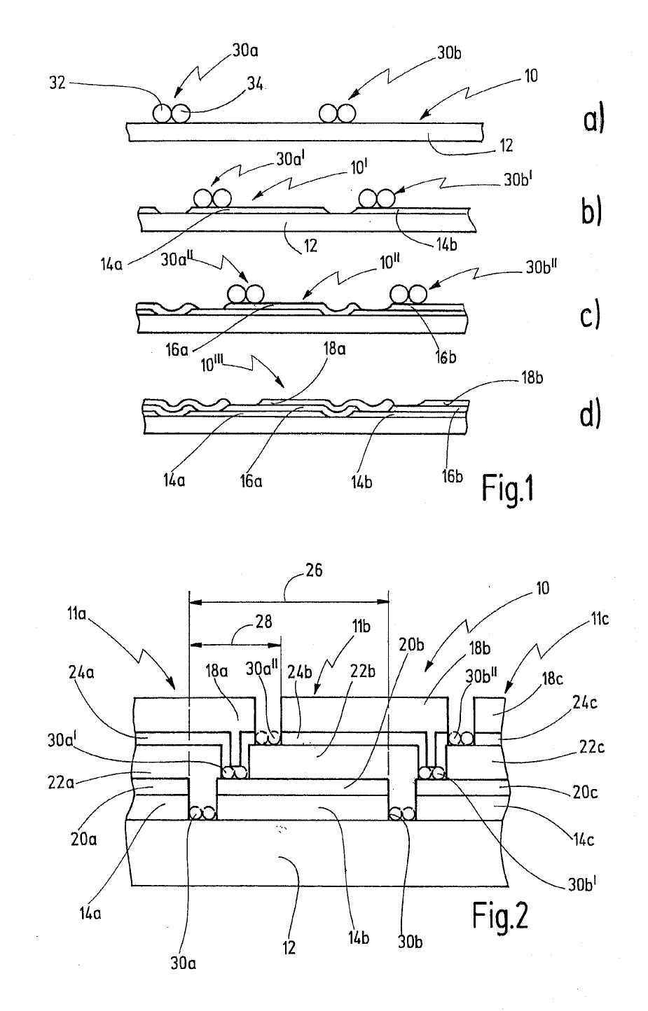

FIG. 2 shows a schematic layer structure of integrated-connected thin-film solar cells, indicating the masking means positions;

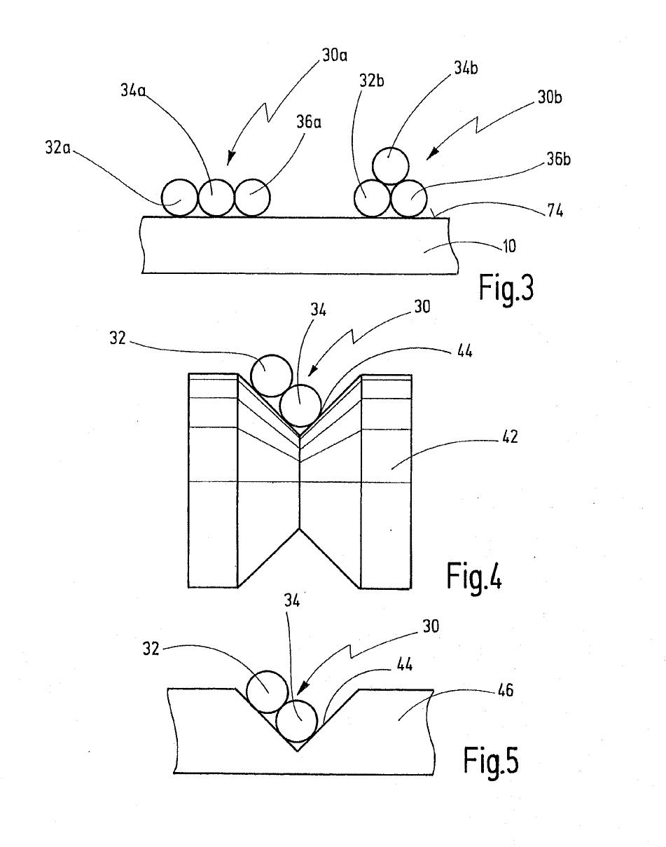

FIG. 3 shows a section through various masking means for carrying out the method according to the invention;

FIG. 4 shows an arrangement for guiding and aligning the masking means;

FIG. 5 shows a further arrangement for guiding and aligning the masking means;

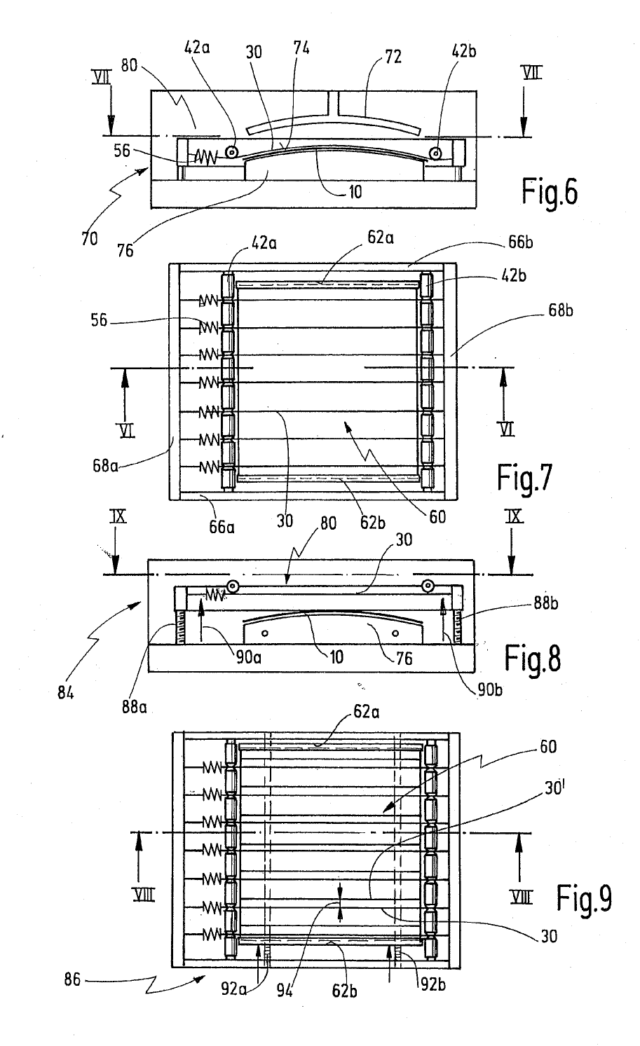

FIG. 6 shows a schematic section through a deposition chamber according to the present invention, along the line VI-VI in FIG. 7;

FIG. 7 shows a schematic section through a masking device along the line VII-VII in FIG. 6;

FIG. 8 shows a schematic section through an offset chamber according to the present invention along the line VIII-VIII in FIG. 9;

FIG. 9 shows a schematic section through an offset device along the line IX-IX in FIG. 8;

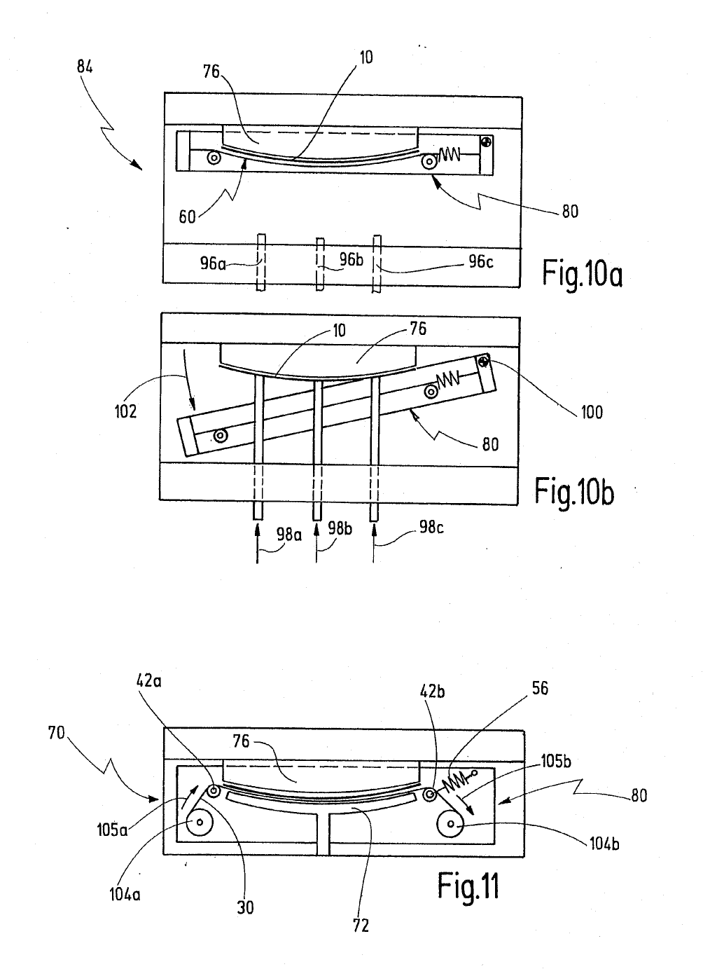

FIG. 10 shows two schematic illustrations of an offset chamber according to the invention;

FIG. 11 shows a further schematic illustration of a deposition chamber according to the invention;

FIG. 12 shows a schematic flowchart of a method according to the invention;

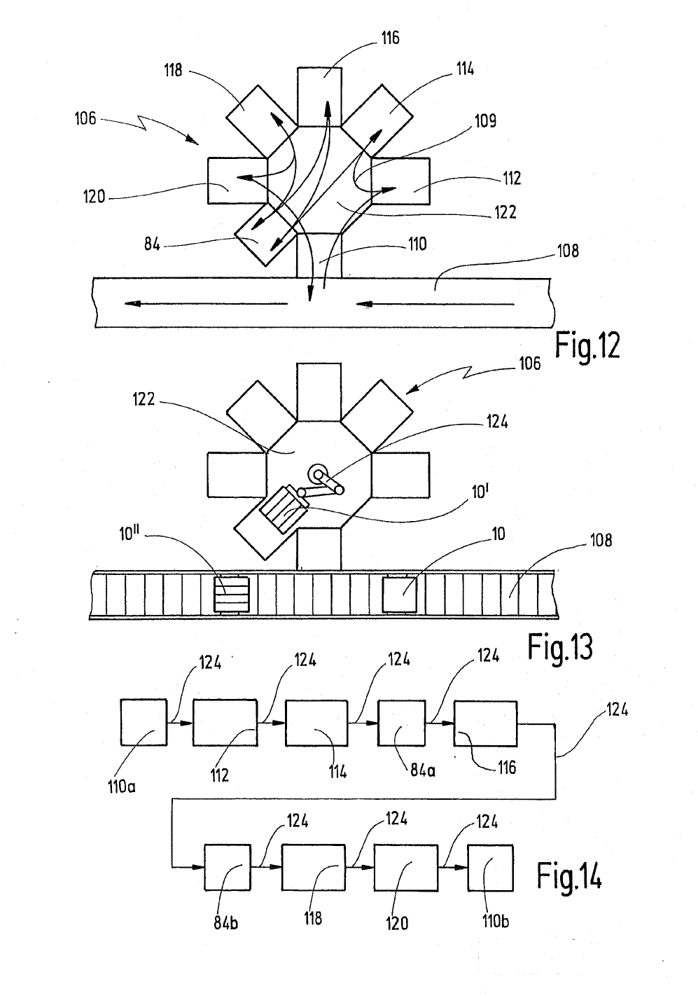

FIG. 13 shows a schematic illustration of an apparatus for carrying out the method according to the invention; and

FIG. 14 shows a further schematic flowchart of the method according to the invention.

FIG. 1 shows a sequence of layer structures of a semi-finished product, which is annotated with the number 10, during the production of series-connected thin-film solar cells, using the method according to the invention.

In FIG. 1a, the semi-finished product 10 consists only of a rigid mount substrate. Masking means 30a, 30b with filaments 32, 34 are applied, and are used for structuring a material layer to be deposited.

FIG. 1b shows the state of the semi-finished product 10′ for example after a first deposition process. In this case, a rear contact layer 14a, 14b has been applied, which is structured corresponding to the masking means 30a, 30b in FIG. 1a. An offset process has resulted in the masking means 30a′, 30b′ assuming a new position on the surface of the semi-finished product, directly alongside their old positions, in order to structure a next layer to be deposited.

FIG. 1c illustrates the semi-finished product 10″ after a second deposition process. In this case, an active layer 16a, 16b has been deposited in a structured form. Another offset process has resulted in the masking means 30a″, 30b″ assuming a new position, and a third material layer to be deposited can now be structured by them.

FIG. 1d shows the layer structure of the semi-finished product 10′″ after this deposition process. A front contact layer 18a, 18b has been deposited in a structured form. This results in an example of a structure of thin-film solar cells with a mount substrate 12, a structured rear contact layer 14, a structured active layer 16 and a structured front contact layer 18. The partial shadowing and therefore the structuring of the material layers 14, 16, 18 has now resulted in the production of a series contact between two solar cell arrangements 14a, 16a, 18a and 14b, 16b, 18b, since the front contact 18a of one solar cell arrangement is connected to the rear contact 14b of the second solar cell arrangement.

The arrangement as shown in FIG. 1 should be understood only as being explanatory and not in a restrictive sense since, in particular, the active layer 16 can be formed from a plurality of sublayers. The rear contact layer 14 advantageously consists of conductive, reflective materials such as silver or aluminium, while the front contact 18 is preferably formed from conductive, transparent materials, such as aluminium-doped zinc oxide.

In the case of thin-film solar cells, the individual layers are formed by deposition methods and other suitable coating and conversion methods. Chemical gas phase deposition is particularly suitable, for example plasma-assisted chemical gas phase deposition or physical gas phase deposition, for example vapour deposition or sputtering.

In this case, a thin film means thin layers of solid substances in the micrometre to nanometre range, at least those which are considerably thinner than a mount substrate. It should also be added that these thickness ratios are not shown to scale in the figures, in order to assist understanding.

FIG. 2 shows a schematic series-connected solar cell arrangement having a further layer sequence of a semi-finished product 10 during the production of thin-film solar cells. The active layer 16 is in this case further subdivided in the form of p-i-n junctions. A junction such as this may, for example, have an n-layer 20a, 20b, 20c with n-doped silicon, an intrinsic absorber layer 22a, 22b, 22c adjacent to it with undoped silicon and, finally, a p-layer 24a, 24b, 24c with p-doped silicon.

Amorphous or crystalline silicon, in particular also microcrystalline or nanocrystalline silicon, can be used for solar cells based on silicon.

The illustrated layer structure should be understood only as an exemplary embodiment; the active layer of thin-film solar cells based on semi-finished products with rigid substrates can likewise contain thin layers with alternative materials such as gallium arsenide, cadmium telluride or, based on CIGS technology, copper, indium, gallium, sulphur or selenium. It is likewise feasible to provide p-n junctions instead of the p-i-n junctions.

It is also self-evident that the method according to the invention can also be used to produce so-called tandem cells or packed solar cells with a plurality of p-i-n or p-n junctions formed one on top of the other, in order to make it possible to produce solar cells with a higher energy yield.

Furthermore, it is self-evident that the mount substrate 12 can also be used as a mount for other passive and active components, such as protection diodes or contact connections, or else can be used to hold elements for protection against environmental influences, for example front covers or encapsulation arrangements.

It is also feasible to use the method according to the invention to suitably connect material layers on the semi-finished product in parallel, thus allowing higher current levels instead of a higher output voltage, as is intended to be achieved by series connection. Any desired combinations of parallel connection and series connection are also feasible.

Indicated by dashed circles, FIG. 2 also shows the various positions to be assumed by the masking means 30a, 30b during production according to the invention of the solar cells 11a, 11b, 11c. As described above, structuring can be achieved by shadowing during a deposition process and subsequently offsetting the masking means 30a, 30b, such that the p-layer 24a of the solar cell 11a makes contact with the n-layer 20b of the solar cell 11b, and thus allows the solar cell 11a to be connected in series with the solar cell 11b.

It should be noted that once again for clarity reasons, the masking means 30 have not been illustrated to scale since, in general, the masking means 30 is considerably thicker than the layer thickness of the material layers to be deposited.

In this context, the normal dimensions of the solar cell 11b produced according to the invention will be described, without any restriction to generality. The cell width is annotated 26 in FIG. 2 and can typically, for example, be in the range from 8 to 12 mm, in particular about 10 mm. In contrast, the process width is annotated 28, as a measure of the losses per unit area of the solar cell, and also of the efficiency loss that is governed by the process. In consequence, in the case of the solar cell 11 which is illustrated by way of example and is produced using a method according to the invention, the process width 28 results from the double offset of the masking means 30, that is to say from about three times the width of the masking means 30.

In FIGS. 1 and 2, the masking means 30 each have two filaments 32, 34 which, for example, may each have a diameter of 0.03 mm to 0.2 mm. In this example, this results in a process width 28 of about 0.18 mm to 1.2 mm, which can be subtracted from the cell width 26, for efficiency analyses. In consequence, depending on the number and size of the filaments of the masking means 30, the method according to the invention makes it possible to achieve a low loss per unit area of from about 12% to values considerably less than 5%.

FIG. 3 shows possible refinements of the cross section of the masking means 30a, 30b in the form of a strand. The masking means 30a and 30b each have 3 filaments which, according to the invention, rest on one another.

The masking means 30a has three filaments 32a, 34a, 36a which are arranged on one plane. This arrangement on the surface 74 of the semi-finished product 10 is particularly highly suitable for preventing short circuits in the material to be deposited. In the ideal, there are three line contacts, and a sufficiently large uncoated area can be formed between them. Even if one of the three line contacts fails, for example by a filament lifting off the surface, thus resulting in the material layer to be deposited entering the area to be shadowed, the other filaments can still allow the surface 74 to be structured.

According to FIG. 3, the masking means 30b has a filament 34b which does not itself rest on the surface 74 of the semi-finished product 10, but is particularly suitable for pressing the filaments 32b, 36b securely onto the surface 74. In this case, because the filament 34b rests on the filaments 32b and 36b of the area to be shadowed, this can also be maintained if the filament 32b and the filament 36b were not to rest on one another.

The filaments 32, 34, 36 illustrated in FIG. 3 all have a circular cross section. This should not be considered a restriction, and, in fact, it is possible to also use filaments with a different shape to this, for example those with oval cross sections, rectangular, square or triangular cross sections, with or without rounded edges. In particular, this makes it possible to increase the number of possible line contacts.

It is also possible to provide filaments with different cross-sectional shapes and sizes in one masking means 30.

The filaments 32, 34, 36 may be formed from metal materials, plastics, glass fibres, aramid fibres or carbon fibres, or else suitable material combinations such as insert-moulded steel cores or mesh materials.

As described above it is necessary to guide and to align the masking means 30 with respect to the semi-finished product 10 so as to assist the filaments 32, 34, 36 in resting on one another. FIG. 4 and FIG. 5 accordingly show two possible ways to guide or align the masking means 30 by a guide roller 42 or a centring strip 46.

FIG. 4 accordingly illustrates a rotationally symmetrical guide roller with a centring means 44 in the form of a V-groove, and FIG. 5 illustrates a fixed centring strip 46 with a centring means 44, likewise in the form of a V-groove.

This ensures that, when the masking means 30 with a plurality of filaments 32, 34 is used according to the invention, alignment is possible on a filament which is annotated with the number 34 in the exemplary embodiments, which is used as a reference for alignment by means of the V-groove. The position of the masking means 30 is therefore unambiguously defined on the basis of the filament 34.

According to the invention, the masking means 30 is prestressed. A force component which can additionally press the filament 34 against the semi-finished product 10 can now be produced particularly advantageously during alignment of the filaments 32, 34 by the centring means 44 with a V-groove on the filament 32.

It is furthermore feasible, with a suitable configuration of the centring means 44, for the exemplary configurations of the masking means 30a, 30b shown in FIG. 3 or other suitable masking means configurations likewise to be aligned with respect to the semi-finished product with the aid of arrangements with guide rollers or centring strips.

It has been found that even a single filament on a rigid mount substrate makes it possible to ensure reliable shadowing, and therefore to prevent short circuits. The use of a filament consisting of a wire with a thickness of 50 micrometres, for example, on a mount substrate composed of glass resulted in sufficiently sharp shadowing. The wire with a diameter such as this is already sufficiently flexible to result in an area contact on a rigid mount substrate as well, thus ensuring reliable shadowing and preventing short circuits.

FIGS. 6 and 7 show a deposition chamber 70 with a hold-down device 80 for carrying out the method according to the invention. First of all, it should be mentioned that the curvature of the semi-finished product 10 is in this case illustrated in an exaggerated form, in order to assist understanding.

Semi-finished products 10 with rigid mount substrates are considered to be stiff and generally have high coefficients of elasticity. In consequence, only minor deformation can occur in order that critical stress characteristic values, for example the bending tensile strength in the case of glass materials, are not exceeded by the deformation process.

The semi-finished product 10 is arranged on a receptacle 76 and is curved in advance with respect to a deposition device 72. This curvature can be produced by the natural weight of the semi-finished product 10 or by suitable means, for example by holders 62a, 62b. The holders 62a, 62b can advantageously also be used to shadow edge areas of the semi-finished product 10 with respect to the deposition device 72, in order to prevent material from being deposited in these areas, and therefore undesirable contacts being made.

A hold-down device 80 is arranged in the deposition chamber 70, which hold-down device 80 has a masking device 60 with masking means 30 for partial shadowing and structuring of the surface 74 of the semi-finished product 10 with respect to the deposition device 72. In order to guide the masking means 30, guide rollers 42a, 42b are associated with them and are provided on frame parts 66a, 66b of the hold-down device. It is particularly advantageous for the guide rollers 42a, 42b to likewise be used to additionally prestress the masking means 30 with respect to the semi-finished product 10. The masking means 30 are prestressed by stressing means 56 in the form of springs. In the illustrated example, the stressing means 56 are integrated directly in the masking means 30 although, nevertheless, other implementations are feasible, in which prestressing forces are introduced into the masking means 30 from the outside.

During the deposition process, the hold-down device 80 can now be used with the masking device 60 to ensure that the semi-finished product 10 is held exactly and securely on the receptacle 76, and the material layer to be deposited is structured.

FIGS. 8 and 9 now show a subsequent method step. The masking means 30 is offset according to the invention in an offset chamber 84 with an offset device 86, for example in order to produce a solar cell arrangement as shown in FIG. 1 or FIG. 2. FIG. 8 shows that the hold-down device 80 has now been lifted off the semi-finished product 10 by means of the masking device 60 with the masking means 30, as indicated by the arrows 90a, 90b. Lifting means 88a, 88b, for example in the form of threaded spindles or pneumatic cylinders, are provided for this purpose. The semi-finished product 10 is also fixed by means of holders 62a, 62b on the receptacle 76.

An offset can now be produced in this way, for example corresponding to the double-headed arrow annotated with the number 94 in FIG. 9. The offset movement is initiated via offset means 92a, 92b which are in turn in the form of threaded spindles or pneumatic cylinders. This results in a relative movement between the semi-finished product 10, which is fixed on the receptacle 76, and the offset device 86. This is followed by a step in which the hold-down device 80 is lowered once again onto the surface 74 of the semi-finished product, in order to apply the masking means 30 and to allow a prestress to be produced with respect to the semi-finished product 10. A further material layer to be structured and to be deposited can now be applied.

It is self-evident that the arrangements of the deposition chamber 76 shown in FIG. 6 and of the offset chamber 84 shown in FIG. 8 can be physically separated or else conversely combined. Both variants are feasible and are influenced, inter alia, by the planned throughput of the installation.

FIG. 10 shows another refinement of an offset chamber 84. FIG. 10a shows an arrangement in which the semi-finished product 10 is arranged on a cover-side receptacle 76, and is held by means of the hold-down device 80 with the masking device 60. At the bottom, fixing means 96a, 96b, 96c are provided, which have not yet engaged with the semi-finished product 10.

In contrast, FIG. 10b now shows a state in which the hold-down device 80 has been removed from the semi-finished product 10 by pivoting. The pivoting movement about a pivoting axis 100 is indicated by the arrow annotated with the number 102. To do this, the fixing means 96a, 96b, 96c must secure the semi-finished product 10 against becoming loose from the receptacle 76. The movement which takes place for this purpose is indicated by the arrows annotated 98a, 98b and 98c. The offset movement of the masking device 60 can now be carried out, for example analogously to FIG. 9.

FIG. 11 shows an alternative configuration of a deposition chamber 76 with the semi-finished product 10 arranged as shown in FIG. 10 on the receptacle 76 provided on the cover side. The deposition device 72 is arranged at the bottom. In this arrangement, the masking means 30 have and are held by buffer means 104a, 104b in the form of filament rollers. The guide rollers 42a, 42b are used to change the direction of the masking means and to apply a prestressing force in the direction of the surface 74 of the semi-finished product 10. A prestressing force in the longitudinal direction of the masking means is introduced by a stressing means 56 in the form of a spring, which acts on the guide roller 42b.

The masking means 30 particularly advantageously carries out a relative movement along its longitudinal direction with respect to the semi-finished product 10, as indicated by the arrows annotated 105a and 105b. This makes it possible to effectively reduce the deposition of material on the masking means 30. In particular, this also makes it possible to move the masking means 30 continuously or quasi-continuously into a cleaning device, in order to allow material residues and other contamination relating to the process to be removed.

In this context, it should also be added that the filaments of the masking means 30 may already rest on one another on the buffer means 104a, 104b, or else can each be fed in individually by a plurality of buffer means, resting on one another only by means of the guide rollers and centring means, in which case they can be separated again after passing the semi-finished product 10, and can be wound up on separate buffer means.

FIGS. 12 and 13 show a flowchart for carrying out the method according to the invention by means of an apparatus 106 in the form of a cluster or cell manufacturing installation, and in this case the process procedure indicated by a process arrow sequence annotated 109. A transport means 108 for feeding the semi-finished products 10, 10′, 10″ in and out is coupled to a lock 110 which is used to decouple the process gas atmosphere or the vacuum on the process side from the environment.

A handling chamber 122 with a handling device 124, for example in the form of a handling robot, ensures handling of the semi-finished product 10′ in the apparatus 106. It is feasible for the hold-down apparatus 80 to be applied to the semi-finished product 10′ with the masking device 60, for example as shown in FIG. 6 and FIG. 7, in the lock 110. As is illustrated in FIG. 12, this allows the semi-finished product 10′ to be introduced into a first chamber 112 for deposition of the rear contact, and, immediately after this, to be introduced into a chamber 114 for deposition of the n-layer.

This is followed by a first offset process, which is carried out in the offset chamber 84, which can be designed as shown in FIG. 7 and, for example but not exclusively, can be provided with the offset device 86. This is followed by a transfer into a chamber 116 for deposition of the i-layer, which is in turn followed by an offset process in the offset chamber 84. A transfer then takes place to a chamber 118 for deposition of the p-layer and, finally, the transfer to a chamber 120 for deposition of the front contact.

After passing through the lock 110 again and being transferred from the process gas atmosphere or the vacuum on the process side to the environment, the semi-finished product 110″, which is now provided with a solar cell arrangement produced according to the invention, can once again be fed to the transport means 108.

Semi-finished products 10 with rigid mount substrates are particularly suitable for producing large-area solar cell arrangements, since the mount substrates of the arrangement provide mechanical strength, thus allowing series-production-compatible handling of even relatively large units. The apparatus 106, illustrated by way of example, for carrying out the method according to the invention makes it possible to process semi-finished products 10 with rigid mount substrates whose base areas cover approximately areas from less than 0.5 m² to more than 5 m². These base areas are advantageously square or rectangular, but may also have other suitable shapes.

It is self-evident that further method steps can be carried out before, between, after or else at the same time as the method according to the invention in order to complete the production of solar cell arrangements.

In particular, these may be cutting and cleaning processes, the fitting of further active and passive components, test and inspection steps as well as lamination or assembly processes. An antireflective coating is furthermore normally applied to the surface of such solar cells, in order to optimize the effect of the incident light.

FIG. 14 finally schematically illustrates one possible procedure for the method according to the invention, which can be carried out using an apparatus as shown in FIG. 12 and FIG. 13.

Alternatively, it is feasible to use the process steps in FIG. 14 to carry out production-line or conveyor belt production, which can be advantageous, for example, when mass production is planned. Two locks 110a, 110b can accordingly be provided on the basis of the illustrated process, one of which is used for the inlet to and the other for the outlet from the process gas atmosphere or the process-dependent vacuum. Process chambers 112, 114, 116, 118 and 120 for deposition of material layers are arranged in between and two offset chambers 84a, 84b for offsetting the masking means 30 are in turn connected between them. The necessary transfer takes place by means of the handling device 124, which is indicated by arrows here.

It should also be added that mixed forms such as a combined production line and cell manufacture are also feasible, particularly when it appears to be possible for a plurality of lines to use expensive manufacturing facilities or else to create buffer options for process protection.

The method according to the invention now makes it possible to produce series-connected thin-film solar cells with rigid mount substrates in a simple and advantageous manner. In particular, the method steps involved in the connection process are carried out in the process gas atmosphere or in the vacuum, without the structuring of the material layers that is required in this case having to be provided on the outside.

This in-situ connection allows expenditure for external apparatuses such as laser cutting installations or mechanical scoring installations to be avoided or reduced. Furthermore, the process quality is improved because fewer lock processes and fewer transfer processes are now required outside the process gas atmosphere or the vacuum.

1. A method for production of series-connected thin-film solar cells comprising the following steps:
arranging a semi-finished product having a rigid mount substrate on a receptacle;
inserting the semi-finished product into a deposition chamber having a deposition device;
providing a masking means being configured as a strand having a plurality of filaments which rest on one another, said masking means being prestressed in a longitudinal direction;
applying said masking device to a surface of said semi-finished product facing the deposition device;
partial shadowing of said surface of said semi-finished product by means of said masking device with respect to said deposition device for structuring a material layer to be deposited;
depositing the material layer onto said semi-finished product; and
releasing said masking device from said surface of said semi-finished product.

2. (canceled)

3. The method according to claim 1, wherein a mount substrate is used which is selected from the group consisting of a glass material, a glass ceramic material, a wafer, a plastic and a metal.

4. The method according to claim 1, wherein said semi-finished product has convex curvature with respect to said deposition device.

5. The method according to claim 1, wherein said masking means carries out a relative movement in a longitudinal direction of said masking means with respect to said semi-finished product during deposition of said material layer.

6. The method according to claim 1, wherein said masking means is moved in and out continuously or quasi-continuously in a longitudinal direction.

7. The method according to claim 1, wherein said masking means is guided by at least one guide roller or is aligned by at least one centering means.

8. The method according to claim 1, wherein said masking means is loaded by a hold-down device transversely with respect to its longitudinal direction, essentially at right angles to said surface of said semi-finished product.

9. The method according to claim 8, wherein said hold-down device comprises at least one guide roller or at least one centering means.

10. The method according to claim 1, wherein said masking means is prestressed in a longitudinal direction by a spring.

11. The method according to claim 1, wherein a plurality of material layers are deposited onto said semi-finished product using a plurality of deposition chambers.

12. The method according to claim 11, wherein said masking means is offset transversely with respect to its longitudinal direction on said surface of said semi-finished product between deposition of said material layers, in order to allow contact or separation of specific material layers.

13. The method according to claim 11, wherein deposition of said material layers and offsetting of said masking means are carried out in an atmosphere selected from the group consisting of a process gas atmosphere and a vacuum.

14. The method according to claim 11, wherein offsetting of said masking means is carried out in a separate offset chamber.

15. The method according to claim 11, wherein a transfer is performed between deposition and offsetting, during which the semi-finished product is still subject to the process gas atmosphere or the vacuum.

16. The method according to claim 1, further comprising a cleaning step for removing dirt or residues of deposited material layers.

17. An apparatus for production of series-connected thin-film solar cells comprising at least one deposition chamber having a deposition device, a receptacle with a rigid mount substrate for holding a semi-finished product, and having a masking device being configured for fitting to said semi-finished product, wherein said masking device comprises a masking means being configured as a strand having a plurality of filaments which rest on one another, wherein said masking means is configured for prestressing in a longitudinal direction and for aligning with respect to said semi-finished product for partial shadowing thereof with respect to said deposition device.

18. (canceled)

19. The apparatus according to claim 17, wherein said receptacle for holding said semi-finished product has convex curvature with respect to said deposition device.

20. The apparatus according to claim 17, further comprising a plurality of deposition chambers for depositing material layers, an offset chamber having an offset device including offset means for offsetting said masking means transversely with respect to a longitudinal direction thereof relative to said surface of said semi-finished product, and a handling chamber including a handling device for feeding said semi-finished product into said chambers.

21. The apparatus according to claim 20, further comprising means for applying a vacuum or a process gas to said chambers.
